(19) United States
(12) Patent Application Publication
(10) Pub. No.: US 2016/0351754 A1
(43) Pub. Date: Dec. 1, 2016

(54) SEMICONDUCTOR LIGHT-EMITTING DEVICE

(71) Applicants: Myeong Ha KIM, Hwaseong-si (KR); Chan Mook LIM, Yongin-si (KR)

(72) Inventors: Myeong Ha KIM, Hwaseong-si (KR); Chan Mook LIM, Yongin-si (KR)

(21) Appl. No.: 15/089,683

(22) Filed: Apr. 4, 2016

(30) Foreign Application Priority Data
Jun. 1, 2015 (KR) 10-2015-0077462

(51) Int. Cl. H01L 33/46; H01L 33/32; H01L 33/06

(52) U.S. Cl. CPC H01L 33/46; H01L 33/06; H01L 33/32

(57) ABSTRACT

A semiconductor light-emitting device having improved light extraction efficiency provided by a reflector including a separation layer. The separation layer may be interposed between first and second Bragg layers including one or more pairs of refractive layers having different refractive indices, the first pairs being stacked on one side of the separation layer and the second pairs being stacked on an opposing side of the separation layer.

### CROSS-REFERENCE TO RELATED APPLICATION

This application claims the priority from Korean Patent Application No. 10-2015-0077462 filed on Jun. 1, 2015, in the Korean Intellectual Property Office, the disclosure of which is incorporated herein by reference in its entirety.

### BACKGROUND

Apparatuses consistent with example embodiments of the present disclosure relate to a semiconductor light-emitting device.

Semiconductor light-emitting devices emit light through electron-hole recombination in response to application of a current. Semiconductor light-emitting devices are widely used as light sources, due to a number of inherent advantages, such as low power consumption, high luminance levels, and compactness. For example, among types of semiconductor light-emitting devices, nitride light-emitting devices have been developed.

Recently, semiconductor light-emitting devices have been adopted for use in backlight units, domestic lighting apparatuses, and vehicle lighting.

However, the range of applications of LEDs has been gradually broadened to include adoption of semiconductor light-emitting devices as light sources for high-current and/or high-power applications. Accordingly, there has been continued research to improve the light-emitting efficiency of semiconductor light-emitting devices. In particular, to improve external light extraction efficiency, there is proposed a semiconductor light-emitting device including a reflector and a method of fabricating the same.

### SUMMARY

Aspects of the example embodiments provide a semiconductor light-emitting device having improved light extraction efficiency.

According to an aspect of an example embodiment, there is provided a semiconductor light-emitting device including a substrate including a first surface and a second surface opposing the first surface, a light-emitting structure disposed on the first surface of the substrate and including a first conductivity-type semiconductor layer, an active layer, and a second conductivity-type semiconductor layer, and a reflector including a first Bragg layer, a separation layer, and a second Bragg layer, the first Bragg layer, the separation layer, and the second Bragg layer sequentially disposed on the second surface of the substrate. The first Bragg layer includes a first plurality of layers alternately stacked, each of the first plurality of layers having a refractive index different from refractive indices of each other layer among the first plurality of layers. The second Bragg layer includes a second plurality of layers alternately stacked, each of the second plurality of layers having a refractive index different from refractive indices of each other layer among the second plurality of layers. And, a thickness of the separation layer is greater than thicknesses of each layer among the first plurality of layers and the second plurality of layers.

The separation layer may be disposed between the first Bragg layer and the second Bragg layer in a direction perpendicular to the second surface of the substrate.

The first Bragg layer may include a first layer having a first refractive index and a second layer having a second refractive index greater than the first refractive index, and the second Bragg layer may include a third layer having a third refractive index and a fourth layer having a fourth refractive index greater than the third refractive index. A refractive index of the separation layer may be less than the second refractive index and the fourth refractive index.

The separation layer may be composed of a material that is the same as at least one of a material of which the first layer is composed and a material of which the third layer is composed.

The separation layer may be directly disposed between the second layer and the fourth layer to be in contact with the second layer and the fourth layer.

In an example embodiment, a thickness of the separation layer may be in the range of 0.8 λ/n to 1.5 λ/n (λ is a wavelength of light and n is a refractive index).

Thicknesses of each layer among the first plurality of layers and the second plurality of layers may be in the range of 0.2 λ/n to 0.6 λ/n (λ is a wavelength of light and n is a refractive index).

The thicknesses of each layer among the first plurality of layers and the second plurality of layers may be equivalent.

The thicknesses of each layer among the first plurality of layers and the second plurality of layers may increase as a distance from the substrate of each layer among the first plurality of layers and the second plurality of layers increases.

The quantity of the first plurality of layers forming the first Bragg layer may be greater than a quantity of the second plurality of layers forming the second Bragg layer.

The thicknesses of each layer among the first plurality of layers and the second plurality of layers may decrease as a distance from the substrate of each layer among the first plurality of layers and the second plurality of layers increases.

The quantity of the first plurality of layers forming the first Bragg layer may be less than a quantity of the second plurality of layers forming the second Bragg layer.

A refractive index of the separation layer may be in the range of 1 to 1.5.

The first Bragg layer may be configured to reflect light within a first wavelength band and the second Bragg layer may be configured to reflect light within a second wavelength band different from the first wavelength band.

According to an aspect of an example embodiment, a semiconductor light-emitting device may include a light-emitting structure including a first conductivity-type semiconductor layer, an active layer, and a second conductivity-type semiconductor layer, and a reflector disposed on one surface of the light-emitting structure and including a plurality of Bragg layers and at least one separation layer interposed between two layers among the plurality of Bragg layers and having a thickness greater than 0.8 λ/n (λ is a wavelength of light and n is a refractive index).

Each layer among the plurality of Bragg layers may include a first layer having a first refractive index and a second layer having a second refractive index greater than the first refractive index, and the thickness of the separation layer may be greater than thicknesses of each layer among the first layer and the second layer.

A first difference between the refractive index of the separation layer and the first refractive index may be less than a second difference between the refractive index of the separation layer and the second refractive index.

In an example embodiment, the separation layer may be disposed between second layers of the two layers among the plurality of Bragg layers.

According to an aspect of an example embodiment, a semiconductor light-emitting device may include a light-emitting structure including a first conductivity-type semiconductor layer, an active layer, and a second conductivity-type semiconductor layer, a Bragg layer disposed on a surface of the light-emitting structure and including a plurality of layers including a first layer having a first refractive index and a second layer having a second refractive index different from the first refractive index and being alternately stacked, and a separation layer interposed between two layers among the plurality of layers of the Bragg layer and having a thickness greater than thicknesses of each layer among the plurality of layers.

The Bragg layer and the separation layer may be formed of dielectric materials.

### BRIEF DESCRIPTION OF THE DRAWINGS

The above and other aspects will be more clearly understood from the following detailed description taken in conjunction with the accompanying drawings, in which:

FIG. 1 is a schematic cross-sectional view of a semiconductor light-emitting device according to an example embodiment;

FIGS. 2 and 3 are schematic cross-sectional views of reflectors according to example embodiments;

FIG. 4 is a graph illustrating characteristics of a semiconductor light-emitting device according to an example embodiment;

FIGS. 5 to 7 are schematic cross-sectional views of semiconductor light-emitting devices according to example embodiments;

FIGS. 8 and 9 illustrate a package including a semiconductor light-emitting device according to an example embodiment;

FIG. 10 is a schematic cross-sectional view of a backlight unit according to an example embodiment;

FIG. 11 is a schematic cross-sectional view of a backlight unit according to an example embodiment;

FIG. 12 is an exploded perspective view schematically illustrating a lamp including a communications module according to an example embodiment;

FIG. 13 is an exploded perspective view schematically illustrating a bar-type lamp according to an example embodiment; and

FIG. 14 illustrates a lighting apparatus employing a light source module according to an example embodiment.

### DETAILED DESCRIPTION OF EXAMPLE EMBODIMENTS

Hereinafter, example embodiments of the present disclosure will be described in detail with reference to the accompanying drawings.

The example embodiments may, however, be exemplified in many different forms and should not be construed as being limited to the specific example embodiments set forth herein. Rather, the example embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the terms “and/or” and “at least one of” includes each and all combinations of at least one of the referred items.

It will be understood that, although the terms first, second, etc. are used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present inventive concept.

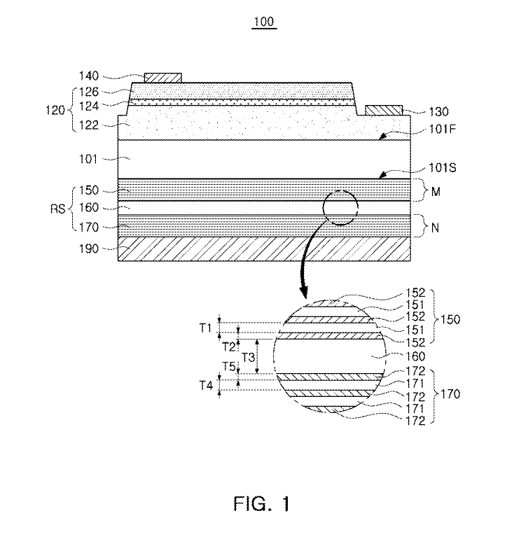

FIG. 1 is a schematic cross-sectional view of a semiconductor light-emitting device according to an example embodiment.

Referring to FIG. 1, a semiconductor light-emitting device 100 includes a substrate 101 having first and second surfaces 101F and 101S, a light-emitting structure 120 disposed on (top of) the first surface 101F of the substrate 101, and a reflector RS disposed on the (bottom of) second surface 101S of the substrate 101. The light-emitting structure 120 includes a first conductivity-type semiconductor layer 122, an active layer 124, and a second conductivity-type semiconductor layer 126. The reflector RS includes first and second Bragg layers 150 and 170 and a separation layer 160. The semiconductor light-emitting device 100 further includes first and second electrodes 130 and 140, and a metal layer 190 disposed below the reflector RS.

The substrate 101 may be provided as a semiconductor growth substrate. The substrate 101 may include an insulating material, a conductive material, or a semiconductor material, such as sapphire, SiC, MgAl₂O₄, MgO, LiAlO₂, LiGaO₂, or GaN. Sapphire is a crystal having Hexa-Rhombo R3c symmetry, has lattice constants of 13.001 Å in a c-axis orientation and 4.758 Å in an a-axis orientation, and has a C-plane (0001), an A-plane (11-20), an R-plane (1-102), and the like. In this case, because the C-plane allows a nitride thin film to be relatively easily grown thereon and achieves stability at high temperatures, sapphire is predominantly utilized as a growth substrate for a nitride. In particular, according to an example embodiment, the substrate 101 may be a transparent substrate.

Meanwhile, although not illustrated in FIG. 1, a plurality of embossing structures may be formed on the first surface 101F of the substrate 101, that is, a growth plane of the semiconductor layers. The embossing structures may improve crystallinity and light-emitting efficiency of semiconductor layers forming the light-emitting structure 120.

A buffer layer may be provided to improve crystallinity of the semiconductor layers forming the light-emitting structure 120. The buffer layer may be disposed on the substrate 101. The buffer layer may be formed of, for example, undoped aluminum gallium nitride (AlₓGa₁₋ₓN) grown at a low temperature.

In an example embodiment, the substrate 101 may be omitted. In this case, the reflector RS may be disposed to be in contact with the light-emitting structure 120.

The light-emitting structure 120 may include the first conductivity-type semiconductor layer 122, the active layer 124, and the second conductivity-type semiconductor layer 126. The first and second conductivity-type semiconductor layers 122 and 126 may be formed of semiconductor materials doped with n-type impurities and p-type impurities, respectively. Inversely, the first and second conductivity-type semiconductor layers 122 and 126 may be formed of semiconductor materials doped with p-type impurities and n-type impurities, respectively. The first and second conductivity-type semiconductor layers 122 and 126 may be formed of a nitride semiconductor, for example, a material having a composition of AlₓIn_{y}Ga_{1-x-y}N (0≦x≦1, 0≦y≦1, and 0≦x+y≦1). Each of the first and second conductivity-type semiconductor layers 122 and 126 may be formed of a single layer, or may include a plurality of layers having different doping concentrations and compositions. Alternatively, the first and second conductivity-type semiconductor layers 122 and 126 may be formed of an AlInGaP-based or AlInGaAs-based semiconductor material. According to the present example embodiment, the first conductivity-type semiconductor layer 122 may be, for example, n-type gallium nitride (n-GaN) doped with silicon (Si) or carbon (C), and the second conductivity-type semiconductor layer 126 may be p-type gallium nitride (p-GaN) doped with magnesium (Mg) or zinc (Zn).

The active layer 124 disposed between the first and second conductivity-type semiconductor layers 122 and 126 may emit light having a predetermined level of energy generated by electron-hole recombination. The active layer 124 may be a layer formed of a single material, such as indium gallium nitride (InGaN), or may have a single quantum well (SQW) or multiple quantum well (MQW) structure in which quantum well layers and quantum barrier layers are alternately stacked. For example, in the case of a nitride semiconductor material, the active layer 124 may have a gallium nitride/indium gallium nitride (GaN/InGaN) structure. When the active layer 124 includes indium gallium nitride (InGaN), crystal defects caused by a lattice mismatch may be decreased by increasing an In content, and internal quantum efficiency of the semiconductor light-emitting device 100 may be increased.

The first and second electrodes 130 and 140 may be respectively disposed on the first and second conductivity-type semiconductor layers 122 and 126 and electrically connected thereto. The first and second electrodes 130 and 140 may be formed of one or more layers of a conductive material. For example, the first and second electrodes 130 and 140 may include at least one of gold (Au), silver (Ag), copper (Cu), zinc (Zn), aluminum (Al), indium (In), titanium (Ti), silicon (Si), germanium (Ge), tin (Sn), magnesium (Mg), tantalum (Ta), chromium (Cr), tungsten (W), ruthenium (Ru), rhodium (Rh), iridium (Ir), nickel (Ni), palladium (Pd), platinum (Pt), and alloys thereof. According to an example embodiment, at least one of the first and second electrodes 130 and 140 may be a transparent electrode, such as indium tin oxide (ITO), aluminum zinc oxide (AZO), indium zinc oxide (IZO), zinc oxide (ZnO), ZnO:Ga (GZO), indium oxide (In₂O₃), tin oxide (SnO₂), cadmium oxide (CdO), cadmium tin oxide (CdSnO₄), or gallium oxide (Ga₂O₃).

Locations and shapes of the first and second electrodes 130 and 140 illustrated in FIG. 1 are example, and the locations and shapes of the first and second electrodes 130 and 140 may be variously modified according to implementation design.

In some example embodiments, an ohmic electrode layer may be further disposed on the second conductivity-type semiconductor layer 126. The ohmic electrode layer may include, for example, p-GaN including high concentration p-type impurities. Alternatively, the ohmic electrode layer may be formed of a metal or a transparent conductive oxide.

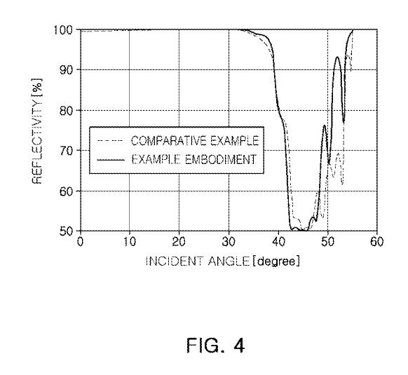

The reflector RS may be disposed on the second (lower) surface 101S of the substrate 101 opposite the first (upper) surface 101F on which the light-emitting structure 120 is disposed. The reflector RS may include the first and second Bragg layers 150 and 170 and the separation layer 160. The reflector RS may be a reflection structure for redirecting light, generated by the active layer 124 and passing through the substrate 101, upwardly of the light-emitting structure 120. Because the reflector RS has the separation layer 160 interposed between the first and second Bragg layers 150 and 170, reflection efficiency may be further improved. The improved reflection efficiency will be described in detail with reference to FIG. 4.

The first and second Bragg layers 150 and 170 may be distributed Bragg reflectors (DBRs). The first and second Bragg layers 150 and 170 may include a plurality of layers alternately stacked, each of the alternately stacked layers having different refractive indices. The first Bragg layer 150 may include a first layer 151, a layer of a low refractive index, and a second layer 152, a layer of a high refractive index, and the second Bragg layer 170 may include a third layer 171, a layer of a low refractive index, and a fourth layer 172, a layer of a high refractive index. The first and second layers 151 and 152 may be alternately disposed at least one time, and the third and fourth layers 171 and 172 may be alternately disposed at least once. That is to say, the first and second layers 151 and 152 may be alternately disposed as (first) pairs, and one or more of the (first) pairs may be provided. Similarly, the third and fourth layers 171 and 172 may be alternately disposed as (second) pairs, and one or more of the (second) pairs may be provided. The first Bragg layer 150 may have a structure in which the first and second layers 151 and 152 are alternately arranged two or more times, and the second Bragg layer 170 may have a structure in which the third and fourth layers 171 and 172 are alternately arranged two or more times. In an example embodiment, the first to fourth layers 151, 152, 171, and 172 are alternately arranged once. That is to say, the first and second layers 151 and 152 may be alternately disposed as a first pair, and the third and fourth layers 171 and 172 may be alternately disposed as a second pair.

The first and second Bragg layers 150 and 170 may be formed of dielectric materials. The first layer 151 and the third layer 171 may include, for example, one of SiO₂ (refractive index: about 1.46), Al₂O₃ (refractive index: about 1.68), and MgO (refractive index: about 1.7), and the first layer 151 and the third layer 171 may be formed of the same material. The second layer 152 and the fourth layer 172 may include may include, for example, one of TiO₂ (refractive index: about 2.3), Ta₂O₅ (refractive index: about 1.8), ITO (refractive index: about 2.0), ZrO₂ (refractive index: about 2.05), and Si₃N₄ (refractive index: about 2.02). The second layer 152 and the fourth layer 172 may be formed of the same material.

Each of the first to fourth layers 151, 152, 171, and 172 may be formed to have a thickness in the range of 0.2 λ/n to 0.6 λ/n, for example, a thickness of λ/4n, in which λ is a wavelength of light, generated by the active layer 124, and n is a refractive index of a corresponding layer. However, the thicknesses of the example embodiment are not limited thereto. The first and second layers 151 and 152 may have a predetermined thickness in the first Bragg layer 150, and the third and fourth layers 171 and 172 may have a predetermined thickness in the second Bragg layer 170. A thickness T1 of the first layer 151 may be greater than a thickness T2 of the second layer 152, and a thickness T4 of the third layer 171 may be greater than a thickness T5 of the fourth layer 172, but the thicknesses of the layers and relative thicknesses between the layers are not limited thereto.

The separation layer 160 may be disposed between the first and second Bragg layers 150 and 170, and may improve the reflectivity of the first and second Bragg layers 150 and 170. Due to presence of the separation layer 160, the first and second Bragg layers 150 and 170 may be spaced apart from each other in a direction perpendicular to the second surface 101S of the substrate 101, and in general perpendicular to a stacking direction of the layers of the semiconductor light-emitting device 100. In particular, the separation layer 160 may be disposed to be in contact with the second layer 152 and the fourth layer 172 between the second layer 152 and the fourth layer 172, layers having high refractive indices in the first and second Bragg layers 150 and 170.

The separation layer 160 may include a dielectric material having a relatively low refractive index, such as a refractive index of about 1 to about 1.5. A refractive index of the separation layer 160 may be lower than refractive indices of the second layer 152 and fourth layer 172, the layers having high refractive indices, and the same as or similar to refractive indices of the first layer 151 and the third layer 171, layers having low refractive indices. For example, the difference between the refractive index of the separation layer 160 and the refractive indices of the first layer 151 and/or the third layer 171 may be less than 10%. The separation layer 160 may include one of SiO₂, Al₂, and MgO, and may be formed of a material that is the same material as the first layer 151 or the third layer 171. The separation layer 160 may be a single layer of uniform material having a constant refractive index throughout.

The separation layer 160 may have a thickness in the range of 0.8 λ/n to 1.5 λ/n, in which λ is a wavelength of light generated by the active layer 124 and n is a refractive index of a corresponding layer. If the thickness of the separation layer 160 is below the above-described range, the effect of improving reflectivity may be insignificant, and if the thickness of the separation layer 160 is above the above-described range, process efficiency and heat dissipation characteristics may be reduced. A thickness T3 of the separation layer 160 may be greater than each of the thicknesses T1, T2, T4, and T5 of the first to fourth layers 151, 152, 171, and 172.

Each of the first and second Bragg layers 150 and 170 configuring the reflector RS may be designed to reflect light having the same wavelength or a different wavelength. For example, each of the first and second Bragg layers 150 and 170 may reflect light within different wavelength bands. According to an example embodiment, the first and second Bragg layers 150 and 170 may have the same structure. When the first Bragg layer 150 includes a total of M first and second layers 151 and 152, and the second Bragg layer 170 includes a total of N third and fourth layers 171 and 172, M and N may be the same or different from each other. Accordingly, based on the separation layer 160, a thickness of the first Bragg layer 150 and a thickness of the second Bragg layer 170 may be appropriately selected.

The reflector RS may be designed to have a high reflectivity of about 95% or more with respect to the wavelength of the light generated in the active layer 124. Such high reflectivity may be achieved by selecting appropriate refractive indices and thicknesses of the first to fourth layers 151, 152, 171, and 172 and the separation layer 160. The number of iteratively stacked structures of the first to fourth layers 151, 152, 171, and 172 may be determined to ensure high reflectivity.

In the present example embodiment, the reflector RS is disposed on the second surface 101S of the substrate 101, but the location of the reflector RS may be modified according to implementation design. For example, the reflector RS may be disposed between the substrate 101 and the light-emitting structure 120 on the first surface 101F of the substrate 101.

The metal layer 190 may be disposed below the reflector RS, and coupled with the reflector RS to further improve the reflection performance. The metal layer 190 may serve to protect the reflector RS if the semiconductor light-emitting device 100 is mounted on a package substrate or the like. The metal layer 190 may include Al, Ag, Ni, Rh, Pd, Ir, Ru, Mg, Zn, Pt, Au, or alloys thereof. Alternatively, the metal layer 190 may be omitted.

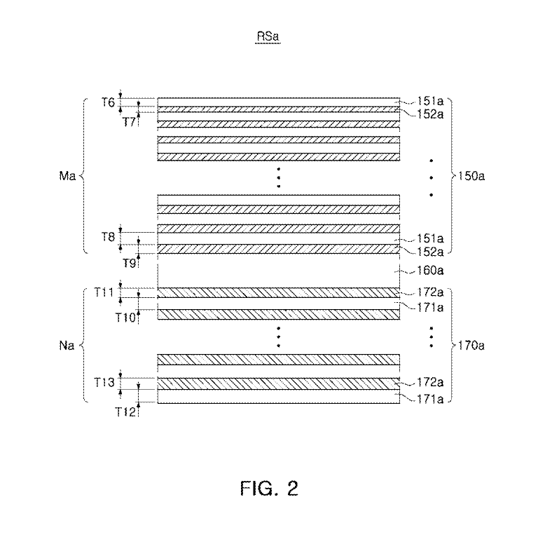

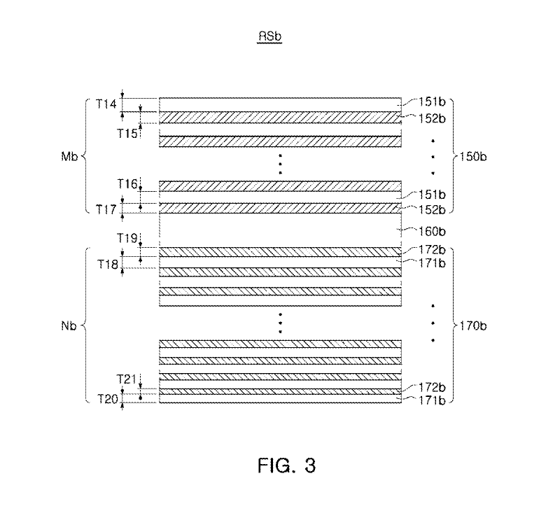

FIGS. 2 and 3 are schematic cross-sectional views of reflectors according to example embodiments. The reflector illustrated in FIGS. 2 and 3 may be the reflector RS of FIG. 1.

Referring to FIG. 2, a reflector RSa includes first and second Bragg layers 150a and 170a and a separation layer 160a. The first Bragg layer 150a may include a first layer 151a having a low refractive index and a second layer 152a having a high refractive index, and the second Bragg layer 170a may include a third layer 171a having a low refractive index layer and a fourth layer 172a having a high refractive index layer.

In the example embodiment, thicknesses of the first to fourth layers 151a, 152a, 171a, and 172a may sequentially increase in a downward direction from a top in contact with the substrate 101 (refer to FIG. 1). FIG. 2 illustrates the gradually increasing thicknesses from a topmost layer having thickness T6 to a bottommost layer having thickness of T12. The thickness of the third layer 171a may increase in succession to the first layer 151a, and the thickness of the fourth layer 172a may increase in succession to the second layer 152a. For example, when λ is a wavelength of incident light, and n is a refractive index of a corresponding layer, the thicknesses of the first layer 151a and the third layer 171a may gradually increase within the range of 0.2 λ/n to 0.6 λ/n, and thicknesses of the second layer 152a and the fourth layer 172a may also gradually increase within the range of 0.2 λ/n to 0.6 λ/n.

More specifically, thicknesses T6 and T7 of the first and second layers 151a and 152a in an upper portion of the first Bragg layer 150a may be respectively lower than thicknesses T8 and T9 of the first and second layers 151a and 152a in a lower portion of the first Bragg layer 150a. Thicknesses T10 and T11 of the third and fourth layers 171a and 172a in an upper portion of the second Bragg layer 170a may be respectively lower than thicknesses T12 and T13 of the third and fourth layers 171a and 172a in a lower portion of the second Bragg layer 170a. The thicknesses T10 and T11 of the third and fourth layers 171a and 172a in the upper portion of the second Bragg layer 170a may be greater than the thicknesses T8 and T9 of the first and second layers 151a and 152a in the lower portion of the first Bragg layer 150a.

The separation layer 160a may be disposed between the first and second Bragg layers 150a and 170a. In particular, the separation layer 160a may be disposed between the second layer 152a and the fourth layer 172a having high refractive indices.

The separation layer 160a may have a thickness in the range of 0.8 λ/n to 1.5 λ/n, in which λ is a wavelength of incident light and n is a refractive index of a corresponding layer. The thickness of the separation layer 160a may be greater than the largest thicknesses T12 and T13 of the thickest third and fourth layers 171a and 172a in the lower portion of the second Bragg layer 170a, among the first to fourth layers 151a, 152a, 171a, and 172a.

When the first Bragg layer 150a includes a total of Ma first and second layers 151a and 152a, and the second Bragg layer 170a includes a total of Na third and fourth layers 171a and 172a, Ma may be greater than Na. As a result, while there is little difference in reflectivity according to the ratio M:N in the reflector RS in which the first to fourth layers 151, 152, 171, and 172 have a constant thickness, as illustrated in FIG. 1, the reflectivity may be improved if the ratio Ma:Na is greater than 1 according to the present example embodiment. For example, the ratio Ma:Na may be 4:1 or more. When the first to fourth layers 151a, 152a, 171a, and 172a and the separation layer 160a includes a total of 40 layers, the separation layer 160a may be the 33rd layer or a layer farther than the 33rd layer from the top.

Referring to FIG. 3, a reflector RSb may include first and second Bragg layers 150b and 170b and a separation layer 160b. The first Bragg layer 150b may include a first layer 151b having a low refractive index and a second layer 152b having a high refractive index, and the second Bragg layer 170b may include a third layer 171b having a low refractive index and a fourth layer 172b a high refractive index.

In the present example embodiment, each thickness of the first to fourth layers 151b, 152b, 171b, and 172b may sequentially decrease in a downward direction from a top in contact with the substrate 101 (refer to FIG. 1), contrary to the reflector RSa described with reference to FIG. 2. The thickness of the third layer 171b may decrease subsequently to the first layer 151b, and the thickness of the fourth layer 172b may decrease subsequently to the second layer 152b.

More specifically, thicknesses T14 and T15 of the first and second layers 151b and 152b in an upper portion of the first Bragg layer 150b may be respectively greater than thicknesses T16 and T17 of the first and second layers 151b and 152b in a lower portion of the first Bragg layer 150b. Thicknesses T18 and T19 of the third and fourth layers 171b and 172b in an upper portion of the second Bragg layer 170b may be respectively greater than thicknesses T20 and T21 of the third and fourth layers 171b and 172b in a lower portion of the second Bragg layer 170b. The thicknesses T18 and T19 of the third and fourth layers 171b and 172b in the upper portion of the second Bragg layer 170b may be smaller than the thicknesses T16 and T17 of the first and second layers 151b and 152b in the lower portion of the first Bragg layer 150b.

The separation layer 160b may be disposed between the first and second Bragg layers 150b and 170b. In particular, the separation layer 160b may be disposed between the second layer 152b and the fourth layer 172b having high refractive indices in the first and second Bragg layers 150b and 170b.

The separation layer 160b may have a thickness in the range of 0.8 λ/n to 1.5 λ/n, in which λ is a wavelength of incident light and n is a refractive index of a corresponding layer. The thickness of the separation layer 160b may be greater than the largest thicknesses T14 and T15 of the thickest first and second layers 151b and 152b in the upper portion of the first Bragg layer 150b, among the first to fourth layers 151b, 152b, 171b, and 172b.

When the first Bragg layer 150b includes a total of Mb first and second layers 151b and 152b, and the second Bragg layer 170b includes a total of Nb third and fourth layers 171b and 172b, Mb may be less than Nb. As a result, reflectivity may be improved when the ratio Mb:Nb is lower than 1 according to present example embodiment. For example, the ratio Mb:Nb may be 1:4 or less. When the first to fourth layers 151b, 152b, 171b, and 172b and the separation layer 160b includes a total of 40 layers, the separation layer 160b may be the 8th layer or a layer nearer than the 8th layer from the top.

FIG. 4 is a graph illustrating characteristics of a semiconductor light-emitting device according to an example embodiment.

In FIG. 4, results of simulation of the reflectivity according to the incident angle of light having a wavelength of 450 nm for a comparative example having a single DBR structure and the example embodiment having the reflector RSa structure, described above with reference to FIG. 2, are illustrated. In the example embodiment of the present disclosure, a structure in which the first layer 151a and the third layer 171a is formed of SiO₂, the second layer 152a and the fourth layer 172a is formed of TiO₂, the separation layer 160a is formed of SiO₂ having a thickness of 300 nm, the reflector RSa includes a total of 39 layers, and the ratio Ma:Na is 7:1, is simulated.

Referring to FIG. 4, a zone in which the reflectivity decreases may appear when the incident angle lies between 35 degrees and 55 degrees. In the zone, the incident angle is substantially equal to a Brewster angle. In the disclosure, such a zone in which the reflectivity decreases is referred to as a Brewster zone. The Brewster zone may appear in the DBR structure. To rectify the decrease of reflectivity in the Brewster zone, the number of iterations of low refractive index layers and high refractive index layers, alternately stacked to form DBR, is increased.

However, as illustrated in FIG. 4, the reflectivity of the Brewster zone may be improved by inserting the separation layer 160a, without increasing the number of iterations of the low refractive index layers and the high refractive index layers. In particular, according to an example embodiment, reflectivity is improved if the incident angle is within the range of 45 degrees to 55 degrees. The zone having improved reflectivity may be adjusted by controlling the thickness (and number, as discussed below) of the separation layer 160a.

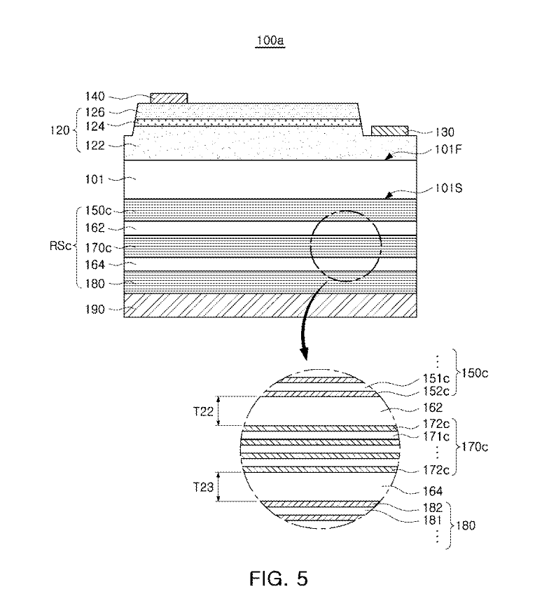

FIGS. 5 to 7 are schematic cross-sectional views of semiconductor light-emitting devices according to example embodiments. In descriptions with reference to FIGS. 5 to 7, descriptions redundant to those provided with reference to FIG. 1 are omitted for brevity.

Referring to FIG. 5, a semiconductor light-emitting device 100a includes a substrate 101, a light-emitting structure 120 disposed on a first surface 101F of the substrate 101, and a reflector RSc disposed on a second surface 101S of the substrate 101. The light-emitting structure 120 includes a first conductivity-type semiconductor layer 122, an active layer 124, and a second conductivity-type semiconductor layer 126. The reflector RSc may include first to third Bragg layers 150c, 170c, and 180 and first and second separation layers 162 and 164. The semiconductor light-emitting device 100a further includes an electrode structure, that is, first and second electrodes 130 and 140, and a metal layer 190 disposed below the reflector RSc.

The reflector RSc may include two separation layers 162 and 164, and thereby three Bragg layers 150c, 170c, and 180 may be disposed apart from each other. The first Bragg layer 150c may include a first layer 151c having a low refractive index and a second layer 152c having a high refractive index; the second Bragg layer 170c may include a third layer 171c having a low refractive index and a fourth layer 172c having a high refractive index; and the third Bragg layer 180 may include a fifth layer 181 having a low refractive index and a sixth layer 182 having a high refractive index.

The first and second separation layers 162 and 164 may be respectively disposed between the second layer 152c and the fourth layer 172c and between the layer 172c and the sixth layer 182, having the high refractive indices, in the first to third Bragg layers 150c, 170c, and 180. Thicknesses T22 and T23 of the first and second separation layers 162 and 164 may be equal or unequal. The number of iterations of the first to sixth layers 151c, 152c, 171c, 172c, 181, and 182 configuring the first to third Bragg layers 150c, 170c, and 180 may be variously selected according to design implementation.

Although two first and second separation layers 162 and 164 are described, the quantity of first and second separation layers 162 and 164 may be variously selected according design implementation, and accordingly the number of Bragg layers 150c, 170c, and 180 may be variously modified.

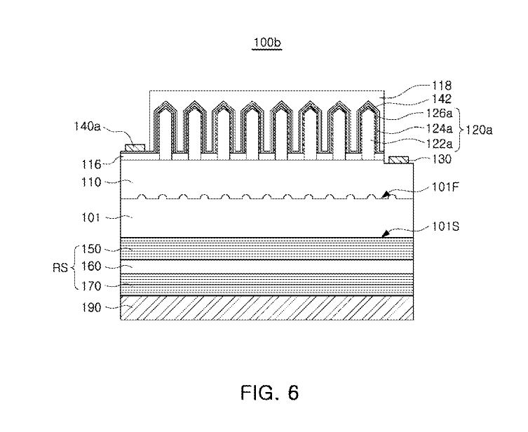

Referring to FIG. 6, a semiconductor light-emitting device 100b includes a substrate 101, a light-emitting nanostructure 120a (indirectly) disposed on a first surface 101F of the substrate 101, and a reflector RS disposed on a second surface 101S of the substrate 101. The light-emitting nanostructure 120a may include a first conductivity-type semiconductor core 122a, an active layer 124a, and a second conductivity-type semiconductor layer 126a, and the reflector RS may include first and second Bragg layers 150 and 170 and a separation layer 160. The semiconductor light-emitting device 100b may further include a base layer 110 disposed between the substrate 101 and the light-emitting nanostructure 120a, an insulating layer 116, a transparent electrode layer 142 and a filling layer 118 covering the light-emitting nanostructure 120a, and an electrode structure including first and second electrodes 130 and 140a, and a metal layer 190 disposed below the reflector RS.

The substrate 101 may include embossing in a growth plane. The base layer 110 may be disposed on the first surface 101F of the substrate 101. The base layer 110 may be a Group III-V compound, such as GaN. The base layer 110 may be, for example, n-GaN doped with n-type impurities. The base layer 110 may provide the growth plane for growing the first conductivity-type semiconductor core 122a, and may be commonly connected to a side of the light-emitting nanostructure 120a to function as a contact electrode.

The insulating layer 116 may be disposed on the base layer 110. The insulating layer 116 may be formed of silicon oxide or silicon nitride. For example, the insulating layer 116 may be formed of at least one of SiOₓ, SiOₓN_{y}, SiₓN_{y}, Al₂O₃, TiN, AlN, ZrO, TiAlN, and TiSiN. The insulating layer 116 may include a plurality of openings exposing a portion of the base layer 110. A diameter, a length, a location, and growth conditions of the light-emitting nanostructure 120a may be determined depending on sizes of the plurality of openings. The plurality of openings may be constructed according to a variety of shapes, such as a circular shape, a tetragonal shape, or a hexagonal shape.

A plurality of light-emitting nanostructures 120a may be disposed in locations corresponding to the plurality of openings. The light-emitting nanostructures 120a may have a core-shell structure including the first conductivity-type semiconductor cores 122a grown from the base layer 110 exposed by the plurality of openings, and the active layers 124a and second conductivity-type semiconductor layers 126a sequentially formed on surfaces of the first conductivity-type semiconductor cores 122a.

The quantity of light-emitting nanostructure 120a included in the semiconductor light-emitting device 100b may be different from those illustrated in FIG. 6, and the semiconductor light-emitting device 100b may include, for example, tens to millions of light-emitting nanostructures 120a. The light-emitting nanostructure 120a may include a lower hexagonal column part and an upper hexagonal pyramid part. In some configurations, the light-emitting nanostructure 120a may have a pyramid shape or a columnar shape. Because the light-emitting nanostructure 120a has such a three-dimensional shape, a light-emitting area is relatively large and light-emitting efficiency may be increased.

The transparent electrode layer 142 may cover upper and side surfaces of the light-emitting nanostructure 120a and may be connected between adjacent light-emitting nanostructures 120a. The transparent electrode layer 142 may include, for example, ITO, AZO, IZO, ZnO, GZO (ZnO:Ga), In₂O₃, SnO₂, CdO, CdSnO₄, or Ga₂O₃.

The filling layer 118 may fill spaces between the adjacent light-emitting nanostructures 120a, and cover the light-emitting nanostructure 120a and the transparent electrode layer 142 disposed on light-emitting nanostructure 120a. The filling layer 118 may be formed of a light-transmitting insulating material, such as SiO₂, SiNₓ, Al₂O₃, HfO, TiO₂, or ZrO.

The first and second electrodes 130 and 140a may be respectively disposed on the base layer 110 and the transparent electrode layer 142 to be connected to the base layer 110 and the second conductivity-type semiconductor layer 126a.

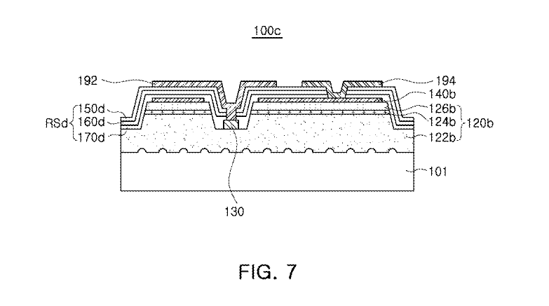

Referring to FIG. 7, a semiconductor light-emitting device 100c includes a substrate 101, a light-emitting structure 120b disposed on the substrate 101, and a reflector RSd disposed on the light-emitting structure 120b. The light-emitting structure 120b includes a first conductivity-type semiconductor layer 122b, an active layer 124b, and a second conductivity-type semiconductor layer 126b, and the reflector RSd includes first and second Bragg layers 150d and 170d and a separation layer 160d. The semiconductor light-emitting device 100c further includes an electrode structure including first and second electrodes 130 and 140b and first and second pad electrodes 192 and 194.

The reflector RSd may be disposed on the light-emitting structure 120b disposed on an upper surface of the substrate 101. The reflector RSd may be formed of an insulating material, and the light-emitting structure 120b is electrically isolated from the first and second pad electrodes 192 and 194. A thickness of the reflector RSd or the number of layers forming the first and second Bragg layers 150d and 170d may be selected in consideration of a thickness of the light-emitting structure 120b or a depth of the first electrode 130 from the upper surface of the light-emitting structure 120b.

The first and second pad electrodes 192 and 194 may be partially connected to the first and second electrodes 130 and 140b, respectively, and extend onto the reflector RSd. The semiconductor light-emitting device 100c may be mounted in such a manner that the first and second pad electrodes 192 and 194 face an external substrate, such as a package substrate. Light emitted from the active layer 124b may be emitted toward the substrate 101.

In the present example embodiment, arrangements and structures of the first and second electrodes 130 and 140b and the first and second pad electrodes 192 and 194 are only example, and the arrangements and structures of the first and second electrodes 130 and 140b and the first and second pad electrodes 192 and 194 may be variously modified according to implementation design. For example, the first electrode 130 may have a via shape passing through the light-emitting structure 120b.

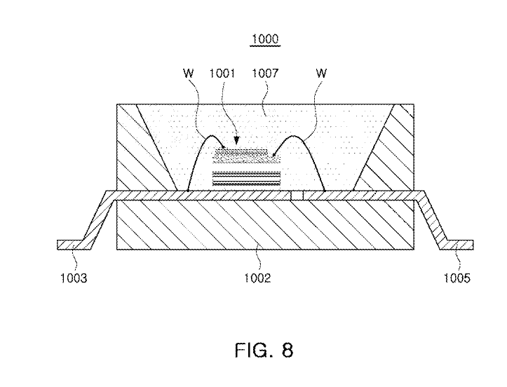

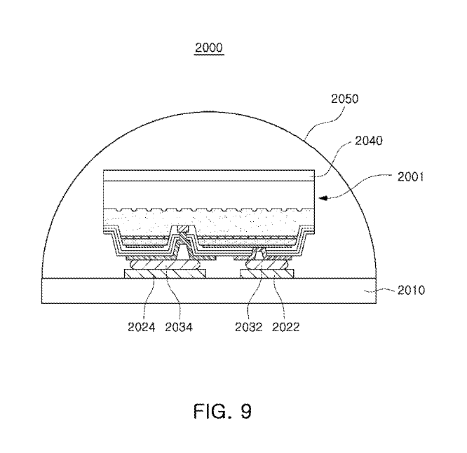

FIGS. 8 and 9 illustrate a package including a semiconductor light-emitting device according to an example embodiment.

Referring to FIG. 8, the semiconductor light-emitting device package 1000 includes a semiconductor light-emitting device 1001, a package body 1002, and a pair of first and second lead frames 1003 and 1005. The semiconductor light-emitting device 1001 may be mounted on the first and second lead frames 1003 and 1005 and electrically connected to the first and second lead frames 1003 and 1005 through wires W. In some configurations, the semiconductor light-emitting device 1001 may be mounted on an area, such as the package body 1002, other than the first and second lead frames 1003 and 1005. The package body 1002 may have a cup shape to improve light reflection efficiency. An encapsulant 1007 formed of a light-transmitting material encapsulates the semiconductor light-emitting device 1001 and the wires W.

In FIG. 8, the semiconductor light-emitting device package 1000 is illustrated as including the semiconductor light-emitting device 1001 having a similar structure to the semiconductor light-emitting device 100 illustrated in FIG. 1. However, the semiconductor light-emitting device package 1000 may include the semiconductor light-emitting devices 100a and 100b described with reference to FIGS. 5 and 6.

Referring to FIG. 9, the semiconductor light-emitting device package 2000 may include a semiconductor light-emitting device 2001, a mounting board 2010, a wavelength conversion layer 2040, and an encapsulant 2050.

The semiconductor light-emitting device 2001 may be mounted on the mounting board 2010 and may be electrically connected to the mounting board 2010 through first and second circuit electrodes 2022 and 2024 and first and second bumps 2032 and 2034. The semiconductor light-emitting device 2001 may be the semiconductor light-emitting device 100c illustrated in FIG. 7, but is not limited thereto. The semiconductor light-emitting device 2001 may be a semiconductor light-emitting device including a reflector according to the example embodiments of the present disclosure.

The mounting board 2010 may be provided as a printed circuit board (PCB), a metal core PCB (MCPCB), a metal PCB (MPCB), a flexible PCB (FPCB), or the like. A structure of the mounting board 2010 may one of various forms.

The wavelength conversion layer 2040 may include at least one fluorescent material excited by light emitted from the semiconductor light-emitting device 2001 and configured to emit light of different wavelengths.

The encapsulant 2050 may be formed to have a dome-shaped lens structure having a convex upper surface. In some configurations, the encapsulant 2050 may have a convex or concave lens structure configured to control an orientation angle of light emitted through the upper surface of the encapsulant 2050.

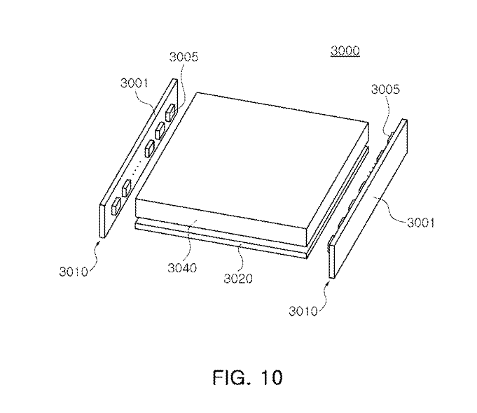

FIG. 10 is a schematic cross-sectional view of a backlight unit according to an example embodiment.

Referring to FIG. 10, a backlight unit 3000 may include a light guide plate 3040 and a light source module 3010 disposed at each side of the light guide plate 3040. The backlight unit 3000 may further include a reflecting plate 3020 disposed below the light guide plate 3040. The backlight unit 3000 may be an edge-type backlight unit.

The light source module 3010 may be provided on only one side of the light guide plate 3040, or provided to the other side of the light guide plate 3040. The light source module 3010 may include a PCB 3001 and a plurality of light-emitting devices 3005 mounted on the PCB 3001. The light-emitting devices 3005 may include the semiconductor light-emitting device 100, 100a, 100b, or 100c illustrated in FIG. 1 and FIGS. 5 to 7, or the semiconductor light-emitting device packages 1000 or 2000 illustrated in FIGS. 8 and 9.

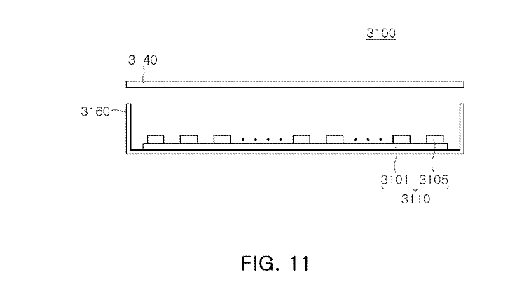

FIG. 11 is a schematic cross-sectional view of a backlight unit according to an example embodiment.

Referring to FIG. 11, a backlight unit 3100 may include a light diffusion plate 3140 and a light source module 3110 disposed below the light diffusion plate 3140. The backlight unit 3100 may further include a bottom case 3160 disposed below the light diffusion plate 3140 and accommodate the light source module 3110. The backlight unit 3100 may be a direct-type backlight unit.

The light source module 3110 may include a PCB 3101 and a plurality of light-emitting devices 3105 mounted on the PCB 3101. The light-emitting devices 3105 may include the semiconductor light-emitting device 100, 100a, 100b, or 100c illustrated in FIG. 1 and FIGS. 5 to 7, or the semiconductor light-emitting device packages 1000 or 2000 illustrated in FIGS. 8 and 9.

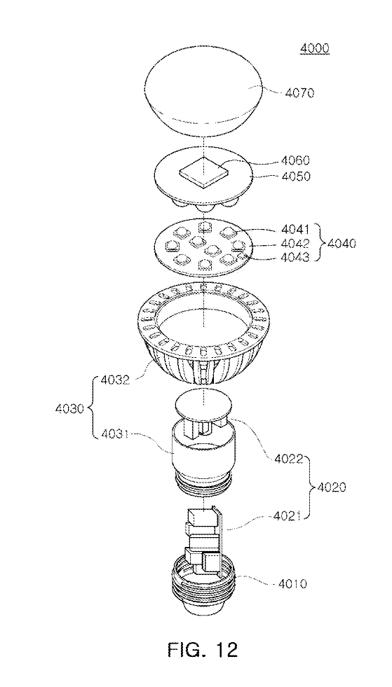

FIG. 12 is an exploded perspective view schematically illustrating a lamp including a communications module according to an example embodiment.

Referring to FIG. 12, a lighting apparatus 4000 includes a socket 4010, a power supply 4020, a heat spreader 4030, a light source module 4040, and a cover 4070. The lighting apparatus 4000 may further include a reflecting plate 4050 and a communications module 4060.

Power supplied to the lighting apparatus 4000 may be applied through the socket 4010. As illustrated in FIG. 12, the power supply 4020 may be separated into a first power supply 4021 and a second power supply 4022. The heat spreader 4030 may include an internal heat spreader 4031 and an external heat spreader 4032. The internal heat spreader 4031 may be directly connected to the light source module 4040 and/or the power supply 4020, to thereby transmit heat to the external heat spreader 4032. The cover 4070 may be configured to uniformly spread light emitted from the light source module 4040.

The light source module 4040 may receive power from the power supply 4020 to emit light to the cover 4070. The light source module 4040 may include one or more light-emitting devices 4041, a circuit board 4042, and a controller 4043. The controller 4043 may be a microprocessor or microcontroller configured to store driving information of the light-emitting devices 4041. The light-emitting devices 4041 may include the semiconductor light-emitting device 100, 100a, 100b, or 100c illustrated in FIG. 1 and FIGS. 5 to 7, or the semiconductor light-emitting device package 1000 or 2000 illustrated in FIGS. 8 and 9.

The reflecting plate 4050 may be disposed on the light source module 4040. The reflecting plate 4050 may function to uniformly spread light from light sources in lateral and rearward directions to reduce glare. The communications module 4060 may be mounted on the reflecting plate 4050, and home-network communications may be implemented through the communications module 4060. For example, the communications module 4060 may be a wireless communications module configured to communicate according to one or more of Zigbee, Wi-Fi, or Li-Fi wireless standards. The communications module 4060 may control functions, such as on/off or brightness adjustment of an interior or exterior lighting apparatus by using a smart phone or a wireless controller. The communications module 4060 may control electronics and car systems in and around the home, such as a TV, a refrigerator, an air conditioner, a door-lock, or an automobile, using a Li-Fi communications module using a wavelength of visible light of the lighting apparatus installed in and around the home. The reflecting plate 4050 and the communications module 4060 may be covered by the cover 4070.

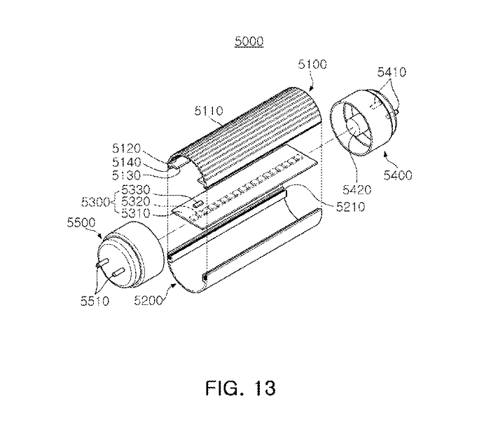

FIG. 13 is an exploded perspective view schematically illustrating a bar-type lamp according to an example embodiment.

Referring to FIG. 13, a lighting apparatus 5000 includes a heat-dissipating member 5100, a cover 5200, a light source module 5300, a first socket 5400, and a second socket 5500.

A plurality of heat-dissipating fins 5110 and 5120 may be disposed on an inner surface and/or an outer surface of the heat-dissipating member 5100 in the form of ridges, and the heat-dissipating fins 5110 and 5120 may be designed to have a variety of shapes and distances therebetween. An overhang-type support 5130 may be formed on an inner side of the heat-dissipating member 5100. The light source module 5300 may be fastened to the support 5130. A fastening protrusion 5140 may be formed at each end portion of the heat-dissipating member 5100 for fastening to the support 5130 and/or sockets 5400 and 5500.

A fastening groove 5210 may be formed in the cover 5200, and the fastening protrusion 5140 of the heat-dissipating member 5100 may be combined with the fastening groove 5210 in a hook-coupling structure. Positions of the fastening groove 5210 and the fastening protrusion 5140 may be exchanged.

The light source module 5300 may include a light-emitting device array. The light source module 5300 may include a PCB 5310, a light source 5320, and a controller 5330. The light source 5320 may include the semiconductor light-emitting device 100, 100a, 100b, or 100c illustrated in FIG. 1 and FIGS. 5 to 7, or the semiconductor light-emitting device package 1000 or 2000 illustrated in FIGS. 8 and 9. The controller 5330 may be a microprocessor or microcontroller configured to store driving information of the light source 5320. Circuit interconnections for operating the light source 5320 may be formed on the PCB 5310. In addition, the PCB 5310 may further include additional components for operating the light source 5320.

The first and second sockets 5400 and 5500 may be a pair of sockets, and may have a structure combined with both end portions of a cylindrical cover unit formed of the heat-dissipating member 5100 and the cover 5200. For example, the first socket 5400 may include an electrode terminal 5410 and a power device 5420, and the second socket 5500 may include a dummy terminal 5510. In addition, an optical sensor and/or a communications module may be embedded in one of the first socket 5400 and the second socket 5500. For example, the optical sensor and/or the communications module may be embedded in the second socket 5500 including the dummy terminal 5510. As another example, the optical sensor and/or the communications module may be embedded in the first socket 5400 including the electrode terminal 5410.

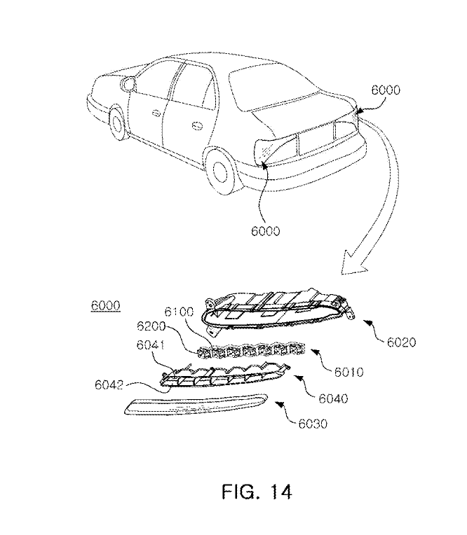

FIG. 14 illustrates a lighting apparatus employing a light source module according to an example embodiment. The lighting apparatus may be implemented as, for example, a taillight of a vehicle.

Referring to FIG. 14, a lighting apparatus 6000 may include a housing 6020 configured to support a light source module 6010, and a cover 6030 configured to cover the housing 6020 and protect the light source module 6010. A lamp reflector 6040 may be disposed on the light source module 6010. The lamp reflector 6040 may include a plurality of reflection planes 6042 and a plurality of through-grooves 6041 formed in bottom surfaces of the reflection planes 6042, and a plurality of light-emitting units 6200 of the light-emitting module 6010 may be exposed on the reflection planes 6042 through the through-grooves 6041.

The lighting apparatus 6000 may have a gently curved structure corresponding to a shape of a corner of the vehicle, and the light-emitting units 6200 may be combined with a frame 6100 in accordance with the curved structure of the lighting apparatus 6000 to form the light source module 6010 having a structure corresponding to the curved structure. Such a structure of the light source module 6010 may be modified according to a design of the lighting apparatus 6000, that is, the taillight. In addition, the number of light-emitting units 6200 to be assembled may be modified according to implementation design.

The lighting apparatus 6000 is a taillight of a vehicle, but the implementation of the lighting apparatus 6000 is not limited thereto. For example, the lighting apparatus 6000 may be implemented as a headlamp of a vehicle or a turn signal installed in a door mirror of a vehicle. In this case, the light source module 6010 may be a multi-level stepped structure corresponding to a curved surface of the headlamp or the turn signal.

As set forth above, a semiconductor light-emitting device having improved light extraction efficiency may be provided by forming a reflector including a separation layer.

While the example embodiments have been described above, it will be apparent to those skilled in the art that modifications and variations could be made without departing from the scope of the present disclosure as defined by the appended claims.

1. A semiconductor light-emitting device comprising:
a substrate comprising:
a first surface; and
a second surface opposing the first surface;
a light-emitting structure disposed on the first surface of the substrate, the light-emitting structure comprising:
a first conductivity-type semiconductor layer;
an active layer; and
a second conductivity-type semiconductor layer; and
a reflector comprising:
a first Bragg layer;
a separation layer; and
a second Bragg layer,
wherein the first Bragg layer, the separation layer, and the second Bragg layer are sequentially disposed on the second surface of the substrate,
wherein the first Bragg layer comprises a first plurality of layers alternately stacked, each of the first plurality of layers having a refractive index different from refractive indices of each other layer among the first plurality of layers,
wherein the second Bragg layer comprises a second plurality of layers alternately stacked, each of the second plurality of layers having a refractive index different from refractive indices of each other layer among the second plurality of layers, and
wherein a thickness of the separation layer is greater than thicknesses of each layer among the first plurality of layers and the second plurality of layers.

2. The semiconductor light-emitting device of claim 1, wherein the separation layer is disposed between the first Bragg layer and the second Bragg layer in a direction perpendicular to the second surface of the substrate.

3. The semiconductor light-emitting device of claim 1, wherein the first Bragg layer comprises:
a first layer having a first refractive index; and
a second layer having a second refractive index greater than the first refractive index,
wherein the second Bragg layer comprises:
a third layer having a third refractive index; and
a fourth layer having a fourth refractive index greater than the third refractive index, and
wherein a refractive index of the separation layer is less than the second refractive index and the fourth refractive index.

4. The semiconductor light-emitting device of claim 3, wherein the separation layer is composed of a material that is the same as at least one of a material of which the first layer is composed and a material of which the third layer is composed.

5. The semiconductor light-emitting device of claim 3, wherein the separation layer is directly disposed between the second layer and the fourth layer in contact with the second layer and the fourth layer.

6. The semiconductor light-emitting device of claim 1, wherein a thickness of the separation layer is in a range of 0.8 λ/n to 1.5 λ/n,
wherein λ is a wavelength of light and n is a refractive index.

7. The semiconductor light-emitting device claim 1, wherein the thicknesses of each layer among the first plurality of layers and the second plurality of layers is in a range of 0.2 λ/n to 0.6 λ/n,
wherein λ is a wavelength of light and n is a refractive index.

8. The semiconductor light-emitting device of claim 1, wherein the thicknesses of each layer among the first plurality of layers and the second plurality of layers are equal.

9. The semiconductor light-emitting device of claim 1, wherein the thicknesses of each layer among the first plurality of layers and the second plurality of layers increases as a distance from the substrate of each layer among the first plurality of layers and the second plurality of layers increases.

10. The semiconductor light-emitting device of claim 9, wherein a quantity of the first plurality of layers forming the first Bragg layer is greater than a quantity of the second plurality of layers forming the second Bragg layer.

11. The semiconductor light-emitting device of claim 1, wherein the thicknesses of each layer among the first plurality of layers and the second plurality of layers decreases as a distance from the substrate of each layer among the first plurality of layers and the second plurality of layers increases.

12. The semiconductor light-emitting device of claim 11, wherein a quantity of the first plurality of layers forming the first Bragg layer is less than a quantity of the second plurality of layers forming the second Bragg layer.

13. The semiconductor light-emitting device of claim 1, wherein a refractive index of the separation layer in the range of 1 to 1.5.

14. The semiconductor light-emitting device of claim 1, wherein the first Bragg layer is configured to reflect light within a first wavelength band and the second Bragg is configured to reflect light within a second wavelength band different from the first wavelength band.

15. A semiconductor light-emitting device, comprising:
a light-emitting structure comprising:
a first conductivity-type semiconductor layer;
an active layer; and
a second conductivity-type semiconductor layer; and
a reflector disposed on a surface of the light-emitting structure, the reflector comprising:
a plurality of Bragg layers; and
at least one separation layer interposed between two layers among the plurality of Bragg layers, the separation layer having a thickness greater than 0.8 λ/n, wherein λ is a wavelength of light and n is a refractive index.

16. The semiconductor light-emitting device of claim 15, wherein each layer among the plurality of Bragg layers comprises:
a first layer having a first refractive index; and
a second layer having a second refractive index greater than the first refractive index, and
wherein the thickness of the separation layer is greater than thicknesses of each layer among the first layer and the second layer.

17. The semiconductor light-emitting device of claim 16, wherein a first difference between the refractive index of the separation layer and the first refractive index is less than a second difference between the refractive index of the separation layer and the second refractive index.

18. The semiconductor light-emitting device of claim 16, wherein the separation layer is disposed between second layers of the two layers among the plurality of Bragg layers.

19-20. (canceled)

21. A semiconductor light-emitting device comprising:
a light-emitting structure configured to emit light;
a reflector disposed opposing a rear surface the light-emitting structure, the reflector configured to reflect light, which is emitted towards the reflector by the light-emitting structure, towards the light-emitting structure,
wherein the reflector comprises:
a first Bragg layer;
a second Bragg layer; and
a separation layer interposed between the first Bragg layer and the second Bragg layer.

22. The semiconductor light-emitting device of claim 21, wherein the first Bragg layer comprises at least one first pair of refractive layers, and
wherein the second Bragg layer comprises at least one second pair of refractive layers.

23-25. (canceled)
